(19) United States
(12) Patent Application Publication
(10) Pub. No.: US 2012/0133617 A1
(43) Pub. Date: May 31, 2012

(54) APPLICATION USING A SINGLE PHOTON AVALANCHE DIODE (SPAD)

(75) Inventor: Kenneth DARGAN, West Lothian (GB)

(73) Assignee: STMicroelectronics (Research & Development) Limited, Marlow (GB)

(21) Appl. No.: 13/241,976

(22) Filed: Sep. 23, 2011

(30) Foreign Application Priority Data
Nov. 30, 2010 (GB) 1020271.1

(51) Int. Cl. G06F 3/042; H05K 13/00

(52) U.S. Cl. 345/175; 29/592.1

(57) ABSTRACT

An control device may control an associated electronic device and parameter for the same. The control device may include a proximity detector. The proximity detector may include a single photon avalanche diode (SPAD). The proximity detector may be configured to control the electronic device and change the parameter.

### FIELD OF THE INVENTION

The present disclosure relates to an application using a single photon avalanche diode (SPAD).

### BACKGROUND OF THE INVENTION

A SPAD is based on a p-n junction device biased beyond its breakdown region. The high reverse bias voltage generates a large enough electric field such that a single charge carrier introduced into the depletion layer of the device can cause a self-sustaining avalanche via impact ionization. The avalanche is quenched, either actively or passively to allow the device to be “reset” to detect further photons. The initiating charge carrier can be photo-electrically generated by a single incident photon striking the high field region. It is this feature which gives rise to the name “Single Photon Avalanche Diode.” This single photon detection mode of operation is often referred to as Geiger Mode.

U.S. Pat. No. 7,262,402 to Niclass et al. discloses an imaging device using an array of SPADs for capturing a depth and intensity map of a scene, when the scene is illuminated by an optical pulse. U.S. Patent Application No. 2007/0182949 to Niclass discloses an arrangement for measuring the distance to an object. The arrangement uses a modulated photonic wave to illuminate the object and an array of SPADs to detect the reflected wave. Various methods of analysis are disclosed to reduce the effects of interference in the reflected wave.

An application where SPAD range detection and proximity detection/accelerometers may be used is with a controller for electronic equipment. Electronic equipment may be fitted with a myriad of different controllers by which a user can interface and interact with the equipment. The different types of controllers include dials, buttons, faders, knobs, switches, etc. Most controllers include some sort of mechanical movement that over time can cause deterioration in the controller and may introduce electrical shorting and mechanical problems. In extreme cases, the mechanical deterioration can cause the controller to completely fail; this often results in the need to replace the electronic equipment.

### SUMMARY OF THE INVENTION

An objective of the present disclosure is to provide an approach to at least some of the problems associated with the prior art.

An objective of the present disclosure is to provide a controller having no moving parts and that can extend the lifetime of the system, particularly when the controller is in constant use. A further object is to provide a fader or slide controller that may not be prone to mechanical problems and does not include bulky components, such as resistors, solenoids, etc.

According to an aspect, a controller may include a proximity detector for controlling a parameter of a device that the controller relates. The proximity detector may comprise an array of SPADs, and an illumination source. The illumination from the illumination source may be reflected by the activator (object) associated with the surface to the array of single photon avalanche diodes.

The array of SPADs may be arranged in rows and columns. Also, the array of SPADs may be connected to a multiplexer and a counter to enable measurement of the reflected illumination. The output from the proximity detector may be passed to control circuitry of a device to enable control of a parameter of the device.

Additionally, the output from the proximity detector may be passed to control circuitry of a device to enable control of a parameter of the device. The controller may measure movement in three axes (X, Y, Z). The movement in each axis may be used for different control functions.

By replacing typical controllers with controllers according to the present disclosure, there may be a number of advantages. The controllers of the present disclosure include no moving parts and may be thus less prone to mechanical damage. As a result, there may be a lesser likelihood of shorting or any other mechanical or electrical problems within the device. The controllers may be inexpensive to manufacture and can be mass produced by silicon wafer processes.

### BRIEF DESCRIPTION OF THE DRAWINGS

Reference may now be made, by way of example, to the accompanying drawings, in which:

FIG. 1 is a diagram for illustrating the determination of phase shift in a SPAD, in accordance with an embodiment of the present disclosure;

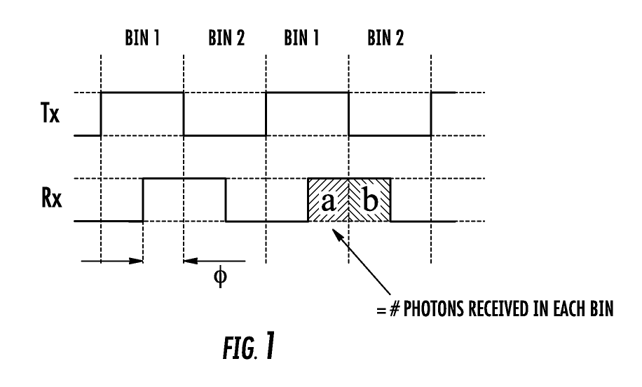

FIGS. 2A-2B are a diagram of a SPAD and an associated timing diagram, in accordance with an embodiment of the present disclosure;

FIG. 3 is a block diagram of a proximity detector, in accordance with an embodiment of the present disclosure; and

FIG. 4 is a block diagram of a controller including a proximity detector, in accordance with an embodiment of the present disclosure.

### DETAILED DESCRIPTION OF THE PREFERRED EMBODIMENTS

The idea that a SPAD can be used as in a ranging application is borne out by the application of a Phase Shift Extraction Method for range determination, although alternative methods exist for range determination using SPADs based on direct time of flight (TOF) measurement. The term ranging in this application is intended to cover all ranging devices and methods including by not limited to ranging devices, proximity devices accelerometers etc. Ranging can occur in a number of applications, including proximity detection, which is relatively easy to implement and inexpensive. Laser ranging is more complex and costly than a proximity detector. Three-dimensional imaging is a high-end application that could be used to recognize gestures and facial expressions.

A proximity sensor is a ranging application. At its simplest, the sensor is capable of indicating the presence or absence of a user or object. Additional computation and illuminator complexity can provide enhanced data such as the range to an object. A typical range is of the order 0.01 m to 0.5 m. In a simple proximity sensor, the illumination source could be a modulated light emitting diode (LED), at a wavelength of about 850 nm.

The next application group is that of laser ranging, where the illumination source is a modulated diode laser. Performance can range from <1 cm to 20 m range (and higher for top end systems) with millimeter accuracy. Requirements on optics are enhanced, with hemispherical lenses and narrow band pass filters being used. A near-field return may result in the introduction of parallax error, i.e. movement of the returned laser spot over the sensor pixel array dependent on distance to object. To overcome these problems, the range device includes calibration functions to enable the subtraction of the electronic and optical delay through the host system. The illumination source wavelength should be visible so that the user can see what is being targeted and is typically around 635 nm.

The third application group is that of 3D cameras. In this application, a pixel array is used to avoid mechanical scanning of the array. Systems can be based on a number of different architectures. Both TOF and modulated illuminator based architectures are used, however, the latter is more robust to ambient light and thus fits best with established photodiode construction. Additional features, such as face and gesture recognition, are applications of this type of ranging device.

Most optical ranging implementations use either stereoscopic, structured light, direct TOF or phase extraction methods to ascertain the range to a target. Stereoscopic approaches use two typical cameras, and can have a heavy computation overhead to extract range. The structured light scheme uses diffractive optics, and the range is computed using a typical camera based on how a known projected shape or matrix of spots is deformed as it strikes the target. The direct TOF method uses a narrow pulsed laser with a time-digital converter (TDC) measuring the difference in time between transmission and first photon reception. Commonly, a “reverse mode” is employed, where the TDC measures the back-portion of time, i.e. the time from first photon reception to next pulse transmission. This scheme may minimize system activity to only the occasions where a photon is detected, and is therefore well matched to tightly controlled, low photon flux levels and medical applications, such as fluorescent lifetime microscopy (FLIM).

The phase extraction method may be helpful method as it is well suited to systems which implement computation of the generalized range equation using existing photodiode technology. It is also robust to background ambient light conditions, and may be adapted to allow for varying illuminator modulation wave-shapes (i.e. sinusoidal or square). This scheme is favored for SPADs in proximity detection applications.

The present disclosure may take advantage of the fact that the phase extraction method system incorporates an inherent ambient light level detection function that can be used in conjunction with a SPAD for many applications, including a controller for electronic equipment. It is important to understand the range equation derivation as it indicates the ease of applicability of SPADs to phase extraction proximity detection and ranging approaches. It also aids in the understanding inherent features, such as ambient light metering and measuring a depth of interest for a specific purpose.

Distance is determined from the speed of light and TOF, as follows:

s=ct.

Where s is distance, c the speed of light, and t is time. For a ranging system however, the distance is doubled due to the fact there are send and receive paths. As such the distance measured in a ranging system s is given by:

s=½ct.

The time shift component (=“t”), due to the photon TOF, is dependent on the modulation frequency and phase shift magnitude of the waveform (t=% shift of the returned waveform×t_{mod}_{_{—}}_{period} and if t_{mod}_{_{—}}_{period}=1/f_{mod}):

$$⇒ t = \frac{φ}{2 π} ∘ \frac{1}{f} \\ ⇒ t = \frac{φ}{2 π ∘ f} .$$

The units are in radians. Then, by substituting the above equation back into the starting equation, the “range equation” is expressed as:

$$⇒ s = \frac{c ∘ φ}{4 π ∘ f} .$$

The critical component in this equation is φ, which is the unknown component of the % shift of the returned waveform. The following section discusses how this can be determined.

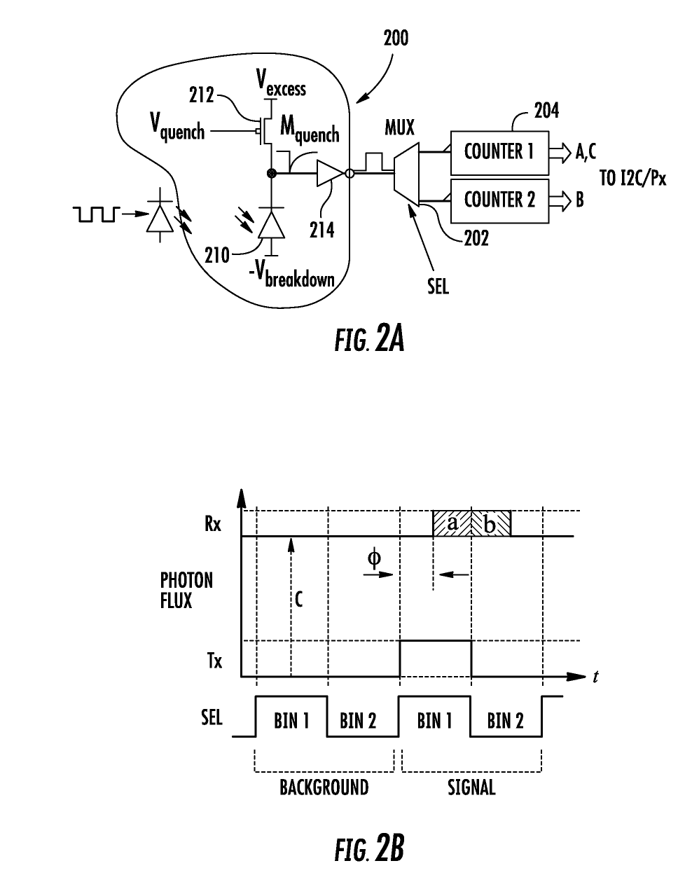

Since the values of c, f and π are all constants; the range result simply scales with φ, (the % shift of the received light waveform in relation to that which was transmitted). FIGS. 2A-2B demonstrate how φ may be determined for a system employing a square wave modulated illuminator. The transmitted and received waveforms are shifted from one another by φ. By measuring the photons that arrive in “a” and “b” in bins 1 and 2 respectively, the value of φ can be determined as follows:

$$\frac{φ}{2 π} = \frac{{b}_{count}}{{( a + b )}_{count}} .$$

In this type of system, there is a range limit set by the illuminator modulation frequency, which is known as the unambiguous range. Photons received from targets that are further away than this range can introduce an aliasing error by erroneously appearing in a legitimate bin for a subsequent measurement. Since determination of range is enabled by the modulation process, it is desirable to maximize the number of edges of the modulation waveform to accumulate data for averaging purposes as fast as possible. However, a high modulation frequency may lower the unambiguous range and introduces more technical complexity in the illumination source drive circuitry. Therefore, two or more different modulation frequencies may be interleaved or used intermittently, so as to reduce or negate the impact of aliased photons via appropriate data processing.

FIG. 2A illustrates a possible implementation of a SPAD based proximity sensor with an associated waveform diagram.

FIG. 2A shows a SPAD 200 connected to a multiplexer 202. The output from the multiplexer passes through counters 1 and 2 (204). The SPAD device shown generally at 200 is of a standard type, including a photo diode 210, a p-type MOSFET 212 and a NOT gate 214.

The timing waveforms are shown in such a way so as to represent the relative photon arrival magnitudes. It can be seen that an extra phase has been added to enable computation of the background ambient light level offset “c,” although this can be significantly reduced by the use of a narrow optical band-pass filter matched to the illumination wavelength if necessary. The element “c” is then accommodated in the computation of received light phase shift φ. The computed results for a, b, c are determined and written into either a temporary memory store or an I2C register. The computation of the phase shift φ, is calculated as follows:

$$φ = \frac{{a}_{count} - c}{{( a + b )}_{count} - 2 c } .$$

The predetermined selection of modulation frequency is performed by dedicated logic or host system that selects a suitable frequency or frequencies for the application of the range sensor. The range sensor of FIG. 2A is dependent on the amount of light that can be transmitted onto the scene, system power consumption, and the target reflectivity.

Since the system shown in FIG. 2A may need to compute the background light condition to ascertain the offset of the returned light pulse from the target, ambient light metering is included. A simplified timing scheme is employed if only the ambient light level data may be required, since the target illumination cycle is not necessary. If a narrow band IR filter is employed in the optical path, the value of c may represent only the content of the filter pass band. This can then be extrapolated to an approximation of the general ambient light conditions.

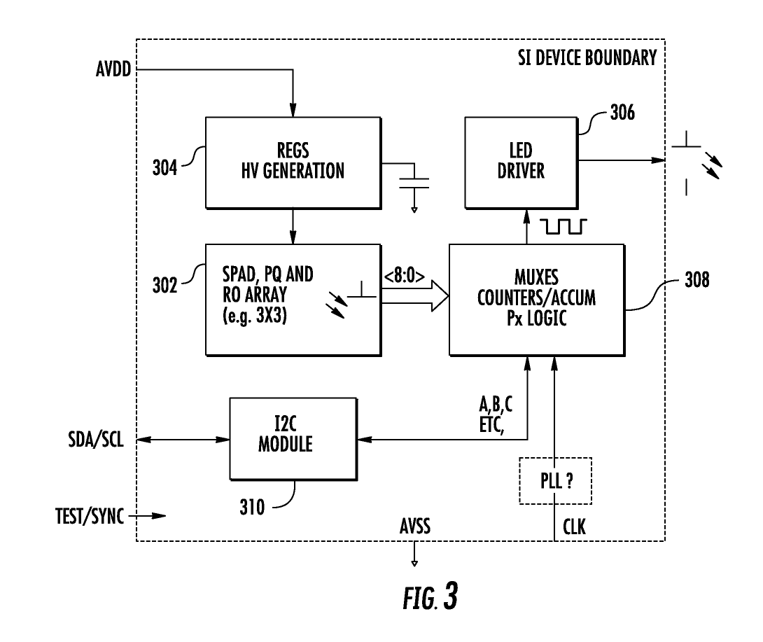

Referring to FIG. 3, a block diagram of a proximity sensor is shown. The proximity sensor 300 includes SPAD function and the quenching thereof in block 302. The quenching can be passive as shown or of any other suitable type. The bias voltage for the SPAD may be provided by a charge pump or any other suitable device 304. The sensor module also includes an LED or other illumination source and an associated driver 306 to ensure that the required modulation is applied to the illumination source.

The sensor may include a distance computation logic module to determine range. Alternatively, this can be located in a host device in which the range sensor is used. The sensor also includes multiplexers and counters 308 and a storage means 310, such as a I2C module or a store. The sensor may also include a Phase Locked Loop (PLL) for clocking and subsequent timed signal generation purposes.

The power consumption of SPADs and their readout circuits are dependent on the incident photon arrival rate. The average power consumption of a ranging system could be reduced by using power saving modes, such as pulsed on/off operation, at a rate of ˜10 Hz for example, at the expense of target motion distortion.

The sensor may be implemented on a 1 mm² die size and the I2C module could also be implemented on an appropriate die. The sensor may include an optical package, an integral IR band pass filter (either coating or inherent in the optical elements) and an optimal field of view of about 30°. As the sensor is not intended to “create an image” but is instead used to ensure that as many photons as possible are detected the optics could be made from injection molded hemispherical elements.

The illuminator source should ideally be of a non-visible wavelength, for example, in the Near Infrared (NIR) band, such as 850 nm. It should be noted that the terms “optical,” “illumination,” and “light” are intended to cover other wavelength ranges in the spectrum and are not limited to the visual spectrum.

The proximity sensor has been described with reference to simple low cost system, although it may be appreciated for certain applications the laser ranging and 3D camera technologies discussed above, could be used. As previously indicated, the proximity sensor of the present disclosure is versatile and can be used in a vast array of different applications. One such application based on a proximity detector is now described.

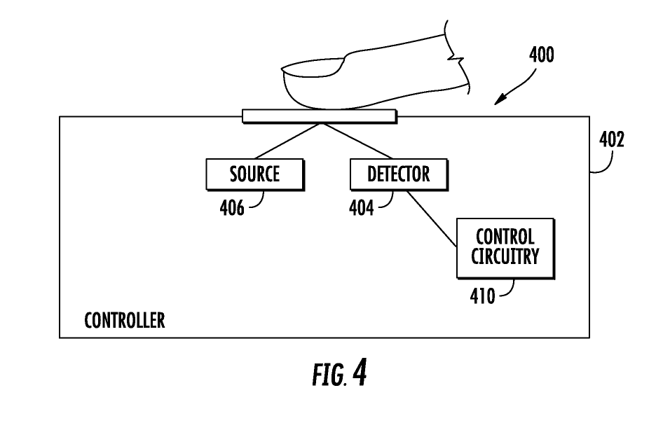

Referring to FIG. 4, a schematic view of a simplified controller 400 is shown. The controller is located on the surface of a device 402 and includes a SPAD proximity detector 404. The controller also includes an illumination source 406. The illumination source is capable of illuminating a controller so that at least some of the illumination is reflected back to the proximity detector 404 in use. A finger or other activator (object) moves on the surface of the controller and the presence and or movement may be used directly or translated to an internal movement before it is detected to effect the required control.

The proximity detector according to the present disclosure is capable of detecting movement in three axes. The movement of a finger on the controller is performed in the X and Y axes of the surface. The movement is measured by determining the sequence of detected reflection on the individual SPAD devices in the SPAD array to determine the movement that has occurred. In addition, movement in the Z axis can also be detected. The SPAD can measure the distance of a finger or other activator from the surface of the controller and use up and down movement relative to the controller to effect a control.

The output of the proximity detector may be used in the control circuitry 410 of the device to generate the required changes to the operation of the device. For example, moving a finger from left to right may cause an increase in some parameters of the device. The parameters may depend on the electronic equipment in question, but can include: volume, tone, visual attributes, other sound attributes, and any other relevant attributes of a device that may need to be controlled.

There may be many different types of controller, having different shapes and sizes. In addition, there may be different movements of a specific controller which relate to different control functions. For example, up and down movement may control volume while movement in the x or y directions could control treble and bass respectively. As a result, a single controller may have multiple functions. If a controller is used for a single purpose, the controller may have a maximum level on the right and a minimum level on the left. The combinations are effectively endless. All that is needed is an understanding of what movements constitute what changes. Details of the relationship between movement and control function or control functions may be stored in the control circuitry of the device.

The illumination source is located in any appropriate location that may enable the controller to be illuminated and reflection to be returned to the proximity detector. The illumination sources may include modulated light emitting diodes (LEDs), modulated lasers, or any other appropriate illumination source. Similarly, the proximity detector can be located on any suitable surface or location as long as it functions as described above.

The present disclosure is may be directed to controllers used in any electronic equipment, including, but not limited to, computers, phones, cameras, PDAs, audio visual equipments, controllers in vehicles and controllers in any appropriate environment.

One embodiment of the controller may be a music slide controller, which includes an elongate SPAD proximity detector responding to finger movement directly or by being translated into an internal movement before it is detected. The finger movement can effect a “sliding” control motion for controlling any output from a device. For example, this embodiment may replace music slide controllers in a recording studio control panel. The advantages of this embodiment may include providing a simple, cost effective approach that is not prone to mechanical damage. The recording studio control panel may include a plurality of slide controllers for controlling different qualities, for example, volume, bass, treble, tone, etc.

The controller as described above may be operated by movement of a finger; however, as will be appreciated by those skilled in the art, other types of pointers or activators are equally relevant. In addition, the relative orientations of the elements of the controller can vary as long as the functional effects of illumination, reflection, and detection are observed. It may be appreciated that many variations of the present disclosure could apply and are intended to be encompassed within the scope of the claims.

1-12. (canceled)

13. A control device for controlling an associated electronic device, the control device comprising:
a proximity detector comprising an array of single photon avalanche diodes (SPAD) and being configured to control the electronic device; and
an illumination source configured to generate illumination to be reflected by an object to said array of SPADs; and
a controller configured to calculate a phase change between transmitted illumination and the illumination received following reflection from the object.

14. The control device of claim 13 further comprising an input surface associated with said array of SPADs; and wherein said an illumination source is configured to generate the illumination to be reflected by the object adjacent said input surface to said array of SPADs.

15. The control device of claim 14 wherein said array of SPADs is arranged in rows and columns.

16. The control device of claim 14 further comprising a multiplexer and an associated counter coupled to said array of SPADs, said multiplexer and counter configured to measure the reflected illumination.

17. The control device of claim 13 wherein said proximity detector is configured to output a signal to control circuitry of the electronic device to enable control of the electronic device.

18. The control device of claim 13 wherein said proximity detector is configured to measure movement in three dimensions.

19. The control device of claim 18 wherein said proximity detector is configured to detect movement of the object in first and second dimensions by determining a sequence of detected illumination on respective SPADs in said array of SPADs, and in a third dimension based upon a calculation of the phase change to detect proximity of the object.

20. The control device of claim 18 wherein said proximity detector is configured to use movement in each dimension for different control functions.

21. The control device of claim 13 further comprising a controller cooperating with said proximity detector.

22. The control device of claim 21 wherein said controller is configured to control the electronic device comprising a telephone device.

23. The control device of claim 21 wherein said controller is configured to control the electronic device comprising a computer device.

24. The control device of claim 21 wherein said controller is configured to control the electronic device comprising a music control device.

25. The control device of claim 13 wherein said proximity detector comprises an elongate slide proximity detector.

26. An electronic device comprising:
a housing;
a proximity detector carried by said housing and comprising at least one single photon avalanche diode (SPAD); and
a controller carried by said housing and coupled to said proximity detector.

27. The electronic device of claim 26 wherein said at least one SPAD comprises an array of SPADs; and further comprising an input surface associated with said array of SPADs, and an illumination source configured to generate illumination to be reflected by an object adjacent said input surface to said array of SPADs.

28. The electronic device of claim 27 wherein said controller is configured to calculate a phase change between transmitted illumination and the illumination received following reflection from the object.

29. The electronic device of claim 27 wherein said array of SPADs is arranged in rows and columns.

30. The electronic device of claim 27 further comprising a multiplexer and an associated counter carried by said housing and coupled to said array of SPADs, said multiplexer and counter configured to measure the reflected illumination.

31. The electronic device of claim 28 wherein said proximity detector is configured to measure movement in three dimensions.

32. The electronic device of claim 31 wherein said proximity detector is configured to detect movement of the object in first and second dimensions by determining a sequence of detected illumination on respective SPADs in said array of SPADs, and in a third dimension based upon a calculation of the phase change to detect proximity of the object.

33. The electronic device of claim 26 wherein said controller is configured to control the operation comprising at least one of a telephone operation, a computer operation, and a music operation.

34. The electronic device of claim 26 wherein said proximity detector comprises an elongate slide proximity detector.

35. A method for making a control device for controlling an associated electronic device, the method comprising:
forming a proximity detector comprising at least one single photon avalanche diode (SPAD) to control the electronic device.

36. The method of claim 35 wherein forming comprises forming the proximity detector to comprise an array of SPADs; and further comprising forming an input surface associated with the array of SPADs, and an illumination source to generate illumination to be reflected by an object adjacent the input surface to the array of SPADs.

37. The method of claim 36 further comprising coupling a controller to the proximity detector to calculate a phase change between transmitted illumination and the illumination received following reflection from the object

38. The method of claim 36 further comprising forming the array of SPADs in rows and columns.

39. The method of claim 36 further comprising coupling a multiplexer and an associated counter to the array of SPADs for measuring the reflected illumination.

40. The method of claim 35 further comprising coupling the proximity detector to output a signal to control the electronic device.
